(19) United States
(12) Patent Application Publication
(10) Pub. No.: US 2013/0128444 A1
(43) Pub. Date: May 23, 2013

(54) Backplane, Backlight Module and LCD Device

(71) Applicants: Yicheng Kuo, Shenzhen (CN); Yuchun Hsiao, Shenzhen (CN); Chong Huang, Shenzhen (CN); Jiahe Cheng, Shenzhen (CN); Chengwen Que, Shenzhen (CN); Quan Li, Shenzhen (CN); Liuyang Yang, Shenzhen (CN)

(72) Inventors: Yicheng Kuo, Shenzhen (CN); Yuchun Hsiao, Shenzhen (CN); Chong Huang, Shenzhen (CN); Jiahe Cheng, Shenzhen (CN); Chengwen Que, Shenzhen (CN); Quan Li, Shenzhen (CN); Liuyang Yang, Shenzhen (CN)

(21) Appl. No.: 13/375,935

(22) PCT Filed: Nov. 29, 2011
(86) PCT No.: PCT/CN2011/083174

§ 371 Date: Dec. 2, 2011

(30) Foreign Application Priority Data
Nov. 18, 2011 (CN) 2011103695776

(51) Int. Cl. H05K 7/18; G09F 13/04

(52) U.S. Cl. 361/679.21; 211/26; 362/97.1

(57) ABSTRACT

The present invention discloses a backplane, a backlight module and an LCD device. A backplane of a backlight module, comprising: a frame; the frame comprises a plurality of mutually joined brackets; bridges are connected among the brackets; locking pieces are fixed to the bridges or the brackets; The backplane is provided with a plurality of locking pieces for fixing PCBs of the backlight module; the tops of the locking pieces fixed with the PCBs are provided with conical peaks; elastic buckling claws extend out of the bottoms of the peaks. The present invention has lower manufacturing cost, saves the material, has simple operation steps and high efficiency, is beneficial to productivity enhancement and further reduces the cost.

### TECHNICAL FIELD

The present invention relates to the field of liquid crystal displays(LCD), and more particularly to a backplane, a backlight module and an LCD device.

### BACKGROUND

An LCD device includes an LCD panel and a backlight module, wherein the bottom of the backlight module is provided with a backplane used for sealing the module and fixing a component in the module. Integral backplanes are used in the existing backplanes and are integrally formed in a mode of metal stamping or plastic injection, causing heavier products and higher material cost of the products. For large-dimension backplanes, because a larger stamping equipment is needed, the cost is higher, the corresponding die dimension is very large, the structure is complicated and the die cost is very high. With increasingly fierce market competition, it is more and more important to effectively reduce the design cost. As a result, the key research direction of each designer lies in saving the material cost and simplifying the assembly technology.

In the traditional backplane, locking pieces are formed by stamping on the backplane for fixing elements such as PCBs and the like according to the needs of different LCD devices; the mode of forming the locking pieces by stamping is not convenient for processing and the installation is not convenient.

### SUMMARY

The aim of the present invention is to provide a backplane, a backlight module and an LCD device with low cost, convenient processing and convenient installation.

The purpose of the present invention is achieved by the following technical schemes.

A backplane of a backlight module, comprising: a frame; the frame comprises a plurality of mutually joined brackets; bridges are connected among the brackets; locking pieces are fixed to the bridges or the brackets; the backplane is provided with a plurality of locking pieces for fixing PCBs of the backlight module; the tops of the locking pieces fixed with the PCBs are provided with conical peaks; elastic buckling claws extend out of the bottoms of the peaks.

Preferably, there are two elastic buckling claws; when the PCBs is removed, the buckling claws need to be pressed and the conical peaks can be taken out. The opposite buckling claws can be conveniently pressed simultaneously for removal; at the same time, the structures of the two buckling claws can also ensure the fixed strength.

Preferably, the roots of the locking pieces connected with the backplane are provided with clamping structures. The clamping structures are adopted on both ends of the locking pieces so that the universality of the locking pieces is higher; at the same time, as long as the conical peaks penetrate through a positioning structure of the backplane, the buckling claws clamp the backplane to achieve the fixation of the locking pieces; the present invention has simple operation steps and high efficiency and is beneficial to productivity enhancement.

Preferably, the roots of the locking pieces connected with the backplane are provided with the riveting columns, Which is a specific fixed structure of the locking pieces and the backplane.

Preferably, the roots of the locking pieces connected with the backplane are provided with screws which is another specific fixed structure of the locking pieces and the backplane.

Preferably, the roots of the locking pieces connected with the backplane are provided with threaded holeswhich is a third specific fixed structure of the locking pieces and the backplane.

Preferably, the roots of the locking pieces connected with the backplane are planes, which is an unfixed form of the locking pieces and the backplane. At this time, the locking pieces are only locked with the PCBs as a supporting action. On an occasion that the PCBs only need supporting without fixing, the locking pieces can save the fixed structure with the backplane and corresponding fixing time, which is beneficial to cost reduction.

Preferably, the locking pieces are integrally formed by plastics. The locking pieces of a plastic structure can enhance an insulation level and avoid generating unnecessary grounding problems caused by the contact between the PCBs and the metal backplane.

A backlight module, comprising: PCBs; the backlight module also comprises the aforementioned backplane; the PCBs are fixed to the locking pieces of the backplane.

An LCD device, comprising: the aforementioned backlight module.

In the present invention, because the structures of the locking pieces are adopted on the backplane, the backplane is formed into a frame structure by a plurality of brackets; the frame is provided with bridges used for installing components such as PCBs and the like; both of the brackets and the bridges can be formed by combining universal shaping pieces; the manufacturing cost is lower and a large number of materials are saved. In addition, the clamping mode of the buckling claws is adopted among the locking pieces and the PCBs; as long as the positioning structure of the PCBs is buckled from the conical peaks, the PCBs can be clamped through the buckling claws and fixed; compared with the modes of screw fixation, riveting fixation and the like, the clamping mode has simple operation steps and high efficiency and is beneficial to productivity enhancement, thus the cost further is reduced.

### BRIEF DESCRIPTION OF FIGURES

FIG. 1 is an installation schematic diagram of the present invention;

FIG. 2 is a schematic diagram of a first locking piece of the present invention;

FIG. 3 is a schematic diagram of a second locking piece of the present invention;

FIG. 4 is a schematic diagram of a third locking piece of the present invention;

FIG. 5 is a schematic diagram of a fourth locking piece of the present invention;

FIG. 6 is a structural diagram of the backplane of example 2 of the present invention;

FIG. 7 is a structural diagram of the backplane of example 3 of the present invention;

FIG. 8 is a structural diagram of the bridges of example 3 of the present invention;

Wherein: 1. backplane; 100. frame; 111. upper bracket; 112. right bracket; 113. lower bracket; 114. left bracket; 115. central bracket; 120. bridge; 121. chute; 122. installing hole; 124. end hinge; 125. tail hinge; 126. cross groove; 127. connecting groove; 300. locking piece; 310. conical peak; 320. buckling claw; 400. backplane; 500. PCB; 810. threaded hole; 811. screw; 820. rivet.

### DETAILED DESCRIPTION

The present invention will further be described in detail in accordance with the figures and the preferred examples.

As shown in FIG. 1, an LCD device, comprising: an LCD panel and a backlight module, wherein the bottom of the backlight module is provided with a backplane 400. The backplane 400 is provided with a plurality of locking pieces 300 used for fixing PCBs 500; the tops of the locking pieces 300 fixed with the PCBs 500 are provided with conical peaks 310; more than two elastic buckling claws 320 extend out of the bottoms of the peaks to form a clamping structure for fixing the PCBs 500; the locking pieces 300 can be integrally formed by plastics.

### Example 1

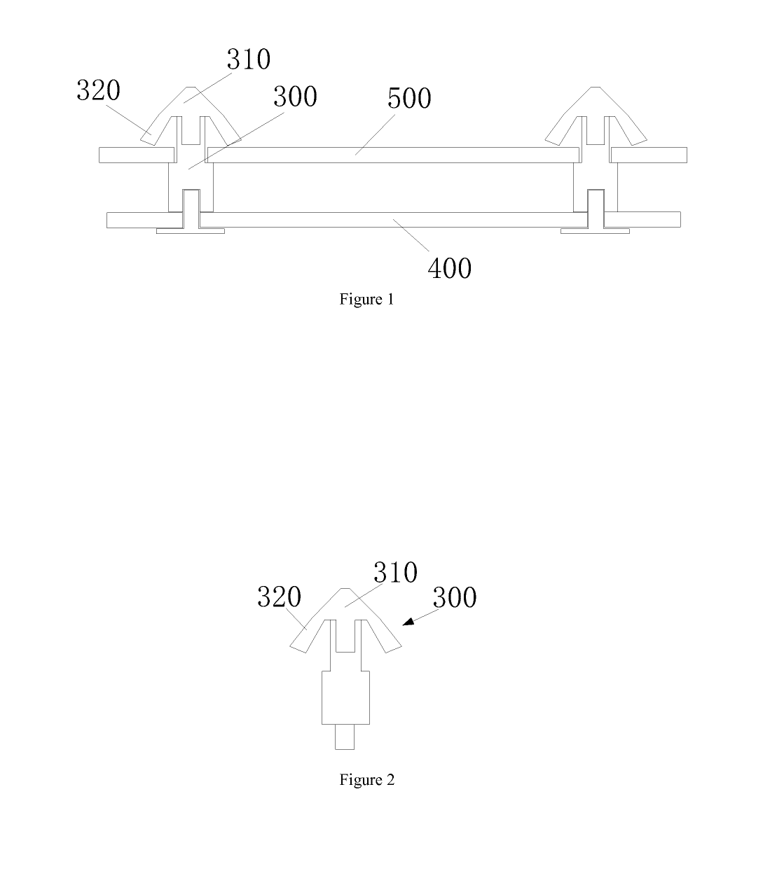

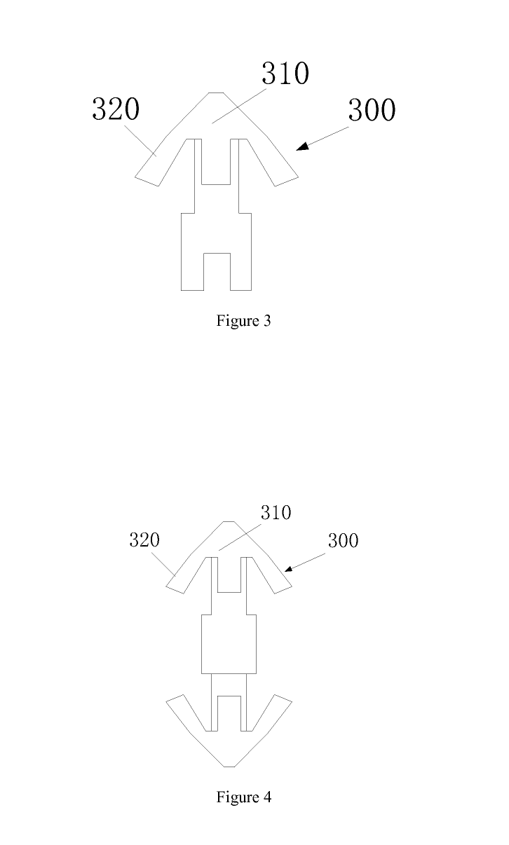

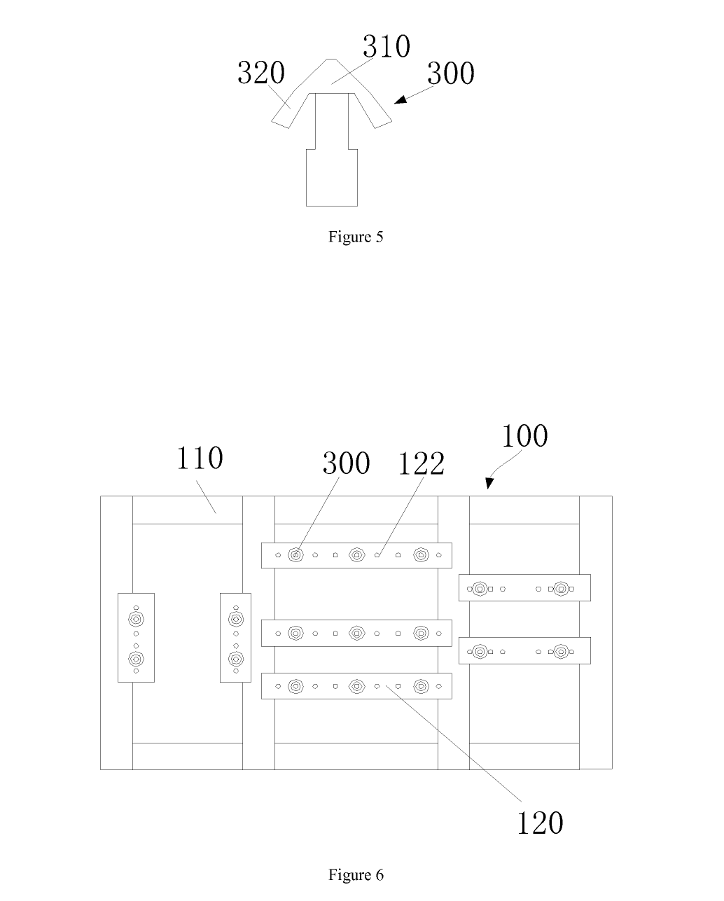

As shown in FIGS. 2 to 4, the locking pieces 300 and the backplane 400 are provided with a fixed structure used for fixing the locking pieces 300 to the backplane 400; the fixed structure can be in any form of riveting columns, screws or threaded holes, or the same clamping structure as the top; correspondingly, the backplane 400 is provided with a positioning structure used for fixing the locking pieces 300; the positioning structure can be in one or more forms of chutes 121, installing holes 122 and the like; the locking pieces 300 is installed on the backplane 400 through the positioning structure. For a larger PCB, after the locking pieces 300 is arranged on the edge and fixed, the locking pieces 300 is possibly unstable; the middle may cave in under the action of gravity; therefore, a part of the locking pieces can be arranged; as shown in FIG. 5, the root of the locking piece can be a plane which is unfixed with the backplane 400 and only fixed with the PCB 500 so as to perform a pure supporting action on the PCBs.

### Example 2

The frame type backplane of FIG. 6, wherein the backplane is combined into a main frame 100 through a plurality of brackets 110 and fixed to the brackets matching the corresponding combination of the bridges 120; the brackets and the bridges are correspondingly provided with the locking pieces 300 required for fixing components of PCBs and the like; in the example, the locking pieces 300 are used as individual parts in the example 1. The main frame 100 of the frame type backplane is provided with a plurality of bridges 120 which are provided with a plurality of installing holes 122. The positions of the installing holes 122 can be set in the corresponding positions of the bridges 120 according to the dimensions of the frequently-used PCBs or other components, namely all the bridges 120 are provided with the corresponding installing holes 122 in accordance with the PCBs of each specification; alternatively, the installing holes can be a series of equidistant standard holes which cover the installing holes 122 required by PCBs of various specifications and are convenient for processing. The locking pieces 300 are installed in the installing holes 122; the installing mode of the locking pieces 300 is the same as the installing mode of example 1; the locking pieces 300 are fixed through screws or a riveted structure formed by the locking pieces 300; certainly, the locking pieces 300 can also be fixed by other modes, not limited to two modes of the example. The locking pieces 300 are arranged in the installing holes 122 of the corresponding positions according to the PCBs of different dimension specifications, so as to achieve the locking of PCBs of the dimension to the backplane. In the example, the installing holes 122 can also be arranged on the brackets, so as to provide more installing positions of the locking pieces 300 to satisfy the backlight module with more components.

### Example 3

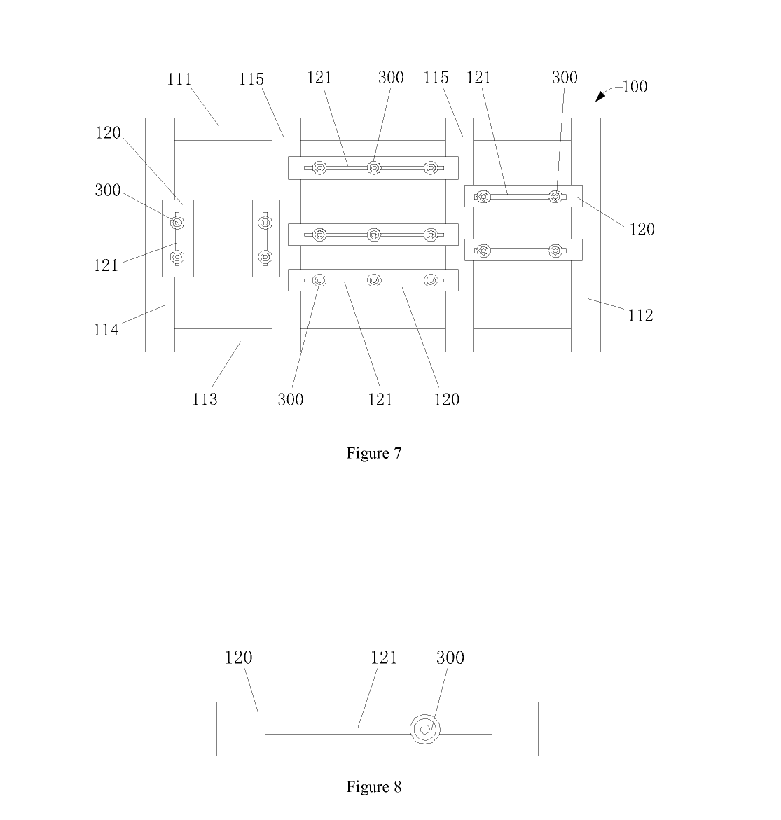

The frame type backplane of FIG. 7, wherein the backplane is combined into a main frame 100 through a plurality of brackets 110 and fixed to the brackets matching the corresponding combination of the bridges 120; the brackets and the bridges are correspondingly provided with the locking pieces 300 required for fixing components of PCBs and the like; in the example, the locking pieces 300 are used as individual parts in the example 1. The main frame 100 of the frame type backplane is provided with a plurality of bridges 120 which are provided with chutes 121 (as shown in FIG. 8, the condition that one bridge is provided with the locking pieces 300); the locking pieces 300 are installed in the chutes 121; the locking pieces 300 are fixed through screws or rivets integrally formed by the locking pieces 300; certainly, the locking pieces 300 can also be fixed by other modes, not limited to two modes of example 1. The locking pieces 300 are arranged in the corresponding positions of the chutes 121 according to the PCBs of different dimension specifications, so as to achieve the locking of PCBs of the dimension. To facilitate the installation, the locking pieces 300 can be installed in advance on the chutes 121 through screws, but the screws are not locked tightly so that the locking pieces 300 can slide on the chutes 121; the locking pieces 300 slide to the corresponding positions in accordance with the dimensions of PCBs; after the PCBs are locked, the screws are locked tightly. Alternatively, the locking pieces 300 are fixed directly through screws or rivets in accordance with the dimensions of the PCBs; and then the PCBs are locked for reducing procedures. In the example, the chutes 121 can also be arranged on the brackets, so as to provide more installing positions of the locking pieces 300 to satisfy the backlight module with more components.

The present invention is described in detail in accordance with the above contents with the specific preferred examples. However, this invention is not limited to the specific examples. For the ordinary technical personnel of the technical field of the present invention, on the premise of keeping the conception of the present invention, the technical personnel can also make simple deductions or replacements, and all of which should be considered to belong to the protection scope of the present invention.

We claim:

1, A backplane of a backlight module, comprising: a frame; said frame comprises a plurality of mutually joined brackets; bridges are connected among said brackets; locking pieces are fixed to said bridges or said brackets; said backplane is provided with a plurality of locking pieces for fixing PCBs of the backlight module; the tops of said locking pieces fixed with said PCBs are provided with conical peaks; elastic buckling claws extend out of the bottoms of said peaks.

2, The backplane of the backlight module of claim 1, wherein there are two said elastic buckling claws.

3, The backplane of the backlight module of claim 1, wherein the roots of said locking pieces connected with the backplane are provided with clamping structures.

4, The backplane of the backlight module of claim 1, wherein the roots of said locking pieces connected with the backplane are provided with riveting columns.

5, The backplane of the backlight module of claim 1, wherein the roots of said locking pieces connected with the backplane are provided with screws.

6, The backplane of the backlight module of claim 1, wherein the roots of said locking pieces connected with the backplane are provided with threaded holes.

7, The backplane of the backlight module of claim 1, wherein the roots of said locking pieces connected with the backplane are provided with planes.

8, The backplane of the backlight module of claim 1, wherein said locking pieces are integrally formed by plastics.

9, A backlight module, comprising: PCBs; said backlight module also comprises the backplane of claim 1; said PCBs are fixed to said locking pieces of the backplane; said backplane comprise a frame; said frame comprises a plurality of mutually joined brackets;
bridges are connected among said brackets; said locking pieces are fixed to said bridges or said brackets; said backplane is provided with a plurality of locking pieces for fixing PCBs of the backlight module; the tops of said locking pieces fixed with said PCBs are provided with conical peaks; elastic buckling claws extend out of the bottoms of said peaks.

10, The backlight module of claim 9, wherein there are two said elastic buckling claws.

11, The backlight module of claim 9, wherein the roots of said locking pieces connected with the backplane are provided with said clamping structures.

12, The backlight module of claim 9, wherein the roots of said locking pieces connected with the backplane are provided with clamping structures.

13, The backlight module of claim 9, wherein the roots of said locking pieces connected with the backplane are provided with screws.

14, The backlight module of claim 9, wherein the roots of said locking pieces connected with the backplane are provided with threaded holes.

15, The backlight module of claim 9, wherein the roots of said locking pieces connected with the backplane are planes.

16, The backlight module of claim 9, wherein said locking pieces are integrally formed by plastics.

17, An LCD device, comprising: said backlight module of claim 9; said backlight module comprises PCBs; said backlight module also comprises a backplane; said PCBs are fixed to the locking pieces of said backplane; said backplane comprise a frame; said frame comprises a plurality of mutually joined brackets; bridges are connected among said brackets;
said locking pieces are fixed to said bridges or said brackets; said backplane is provided with a plurality of locking pieces for fixing PCBs of the backlight module; the tops of said locking pieces fixed with said PCBs are provided with conical peaks; elastic buckling claws extend out of the bottoms of said peaks.

18, The LCD device of claim 17, wherein there are two said elastic buckling claws.

19, The LCD device of claim 17, wherein the roots of said locking pieces connected with the backplane are planes.

20, The LCD device of claim 17, wherein said locking pieces are integrally formed by plastics.
